(19) United States
(12) Patent Application Publication
(10) Pub. No.: US 2024/0321813 A1
(43) Pub. Date: Sep. 26, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Syotaro ONO, Kanazawa Ishikawa (JP); Hisao ICHIJO, Kanazawa Ishikawa (JP); Hiroaki YAMASHITA, Kanazawa Ishikawa (JP)

(21) Appl. No.: 18/464,738

(22) Filed: Sep. 11, 2023

(30) Foreign Application Priority Data
Mar. 20, 2023 (JP) 2023-044514

(51) Int. Cl. H01L 23/00; H01L 23/495

(52) U.S. Cl. CPC H01L 24/73; H01L 23/49513; H01L 24/05; H01L 24/32; H01L 24/40; H01L 24/41; H01L 24/48; H01L 24/49; H01L 23/49562; H01L 2224/05567; H01L 2224/05624; H01L 2224/32245; H01L 2224/4005; H01L 2224/40091; H01L 2224/40245; H01L 2224/40499; H01L 2224/41051; H01L 2224/4805; H01L 2224/48245; H01L 2224/48476; H01L 2224/48499; H01L 2224/49111; H01L 2224/49175; H01L 2224/73221; H01L 2224/73263; H01L 2224/73265; H01L 2924/01028; H01L 2924/01079; H01L 2924/10161; H01L 2924/13055; H01L 2924/13091

(57) ABSTRACT

A semiconductor device according to an embodiment includes: a die pad including an upper surface; a semiconductor chip provided on the upper surface, the semiconductor chip including a rectangular shape, and the semiconductor chip including an element region, and a termination region surrounding the element region; a first electrode provided on the semiconductor chip; a second electrode provided on the semiconductor chip; a first connector provided above the termination region, the first connector including a portion covering each of the four sides of the rectangular shape when viewed from above, and the first connector being electrically connected to the first electrode; and a sealing resin sealing a periphery of the semiconductor chip and the first connector.

### CROSS-REFERENCE TO RELATED APPLICATION

This application is based upon and claims the benefit of priority from Japanese Patent Application No. 2023-044514, filed on Mar. 20, 2023, the entire contents of which are incorporated herein by reference.

### FIELD

Embodiments described herein relate generally to semiconductor device.

### BACKGROUND

A semiconductor device having a semiconductor chip such as a metal oxide semiconductor field effect transistor (MOSFET) is used for applications such as power conversion. For example, when semiconductor device described above is a vertical MOSFET, a source electrode provided on an upper surface of the semiconductor chip is connected to a connector provided on the MOSFET, for example.

### BRIEF DESCRIPTION OF THE DRAWINGS

FIG. 1 is a schematic top view of the semiconductor device according to a first embodiment.

FIG. 2 is a schematic cross-sectional view of the semiconductor device according to the first embodiment.

FIG. 3 is a schematic cross-sectional view of the semiconductor device according to the first embodiment.

FIG. 4 is a schematic cross-sectional view of the semiconductor device according to the first embodiment.

FIG. 5 is a schematic cross-sectional view of the semiconductor device according to the first embodiment.

FIG. 6 is a schematic top view of the semiconductor device as a comparative embodiment of the first embodiment.

FIG. 7 is a schematic cross-sectional view of the semiconductor device as the comparative embodiment of the first embodiment.

FIG. 8 is a schematic cross-sectional view of the semiconductor device according to a second embodiment.

FIG. 9 is a schematic cross-sectional view of the semiconductor device according to a third embodiment.

FIG. 10 is a schematic top view of the semiconductor device according to a fourth embodiment.

FIG. 11 is a schematic top view of the semiconductor device according to a fifth embodiment.

FIG. 12 is a schematic top view of the semiconductor device according to a sixth embodiment.

FIG. 13 is a schematic top view of the semiconductor device according to a seventh embodiment.

FIG. 14 is a schematic top view of the semiconductor device according to an eighth embodiment.

### DETAILED DESCRIPTION

Hereinafter, embodiments of the present disclosure will be described with reference to the drawings. Note that in the following description, the same members and the like are denoted by the same reference numerals, and description of members and the like once described is appropriately omitted.

In this specification, in order to illustrate the positional relationship of parts and the like, the upward direction of the drawings may be referred to as “upper”, and the downward direction of the drawings may be referred to as “lower”. Here, the terms “up” and “down” do not necessarily indicate a relationship with the direction of gravity.

### First Embodiment

A semiconductor device according to the present embodiment includes: a die pad including an upper surface; a semiconductor chip provided on the upper surface, the semiconductor chip including a rectangular shape, and the semiconductor chip including an element region, and a termination region surrounding the element region; a first electrode provided on the semiconductor chip; a second electrode provided on the semiconductor chip; a first connector provided above (on) the termination region, the first connector including a portion covering each of the four sides of the rectangular shape when viewed from above, and the first connector being electrically connected to the first electrode; and a sealing resin sealing a periphery of the semiconductor chip and the first connector.

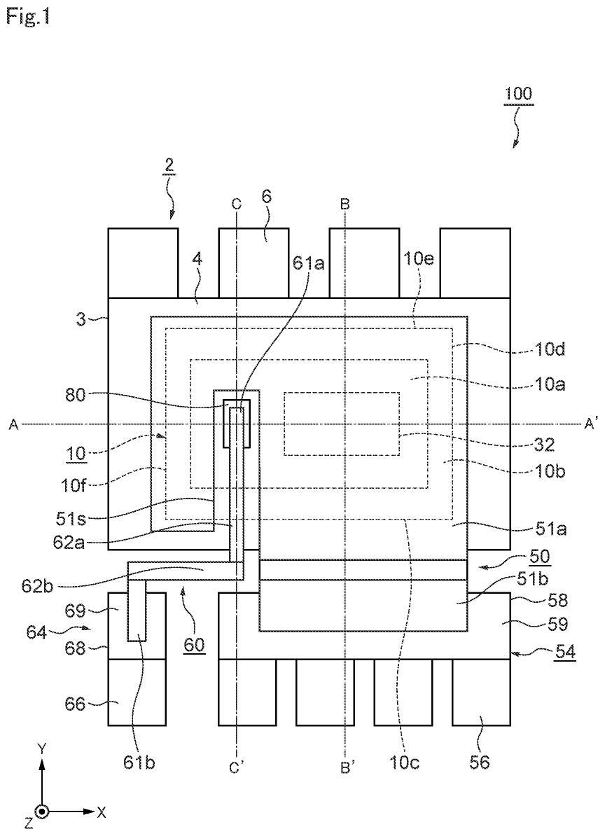

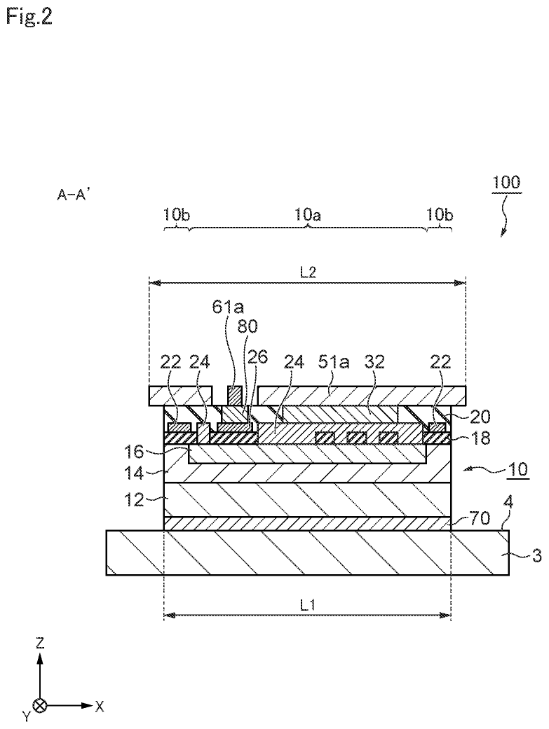

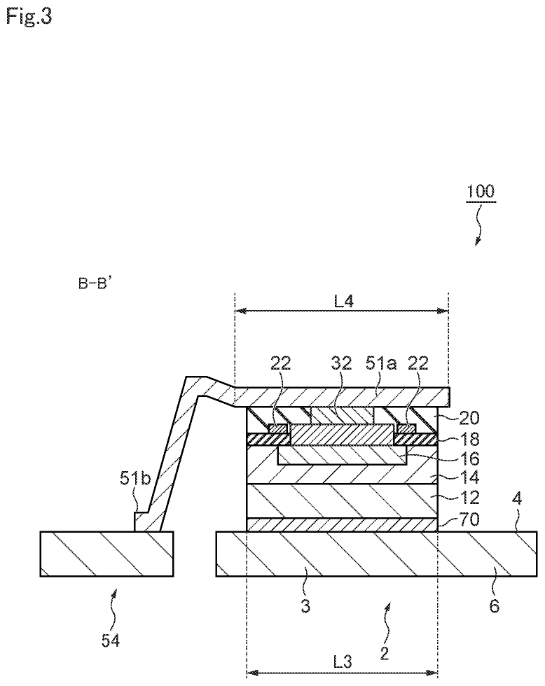

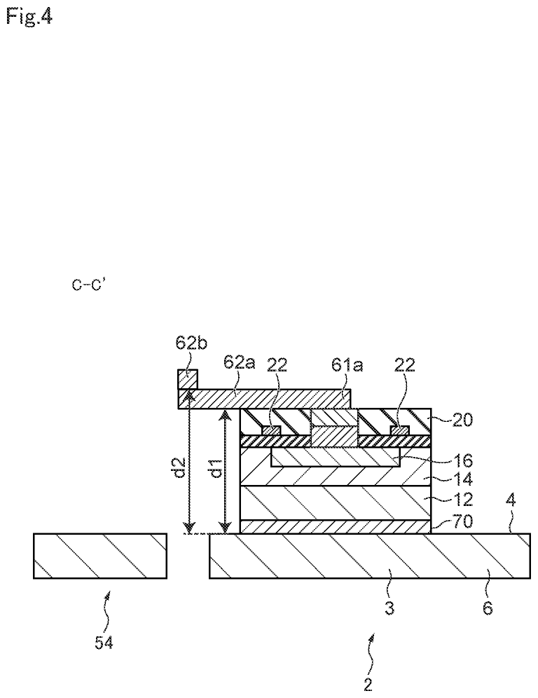

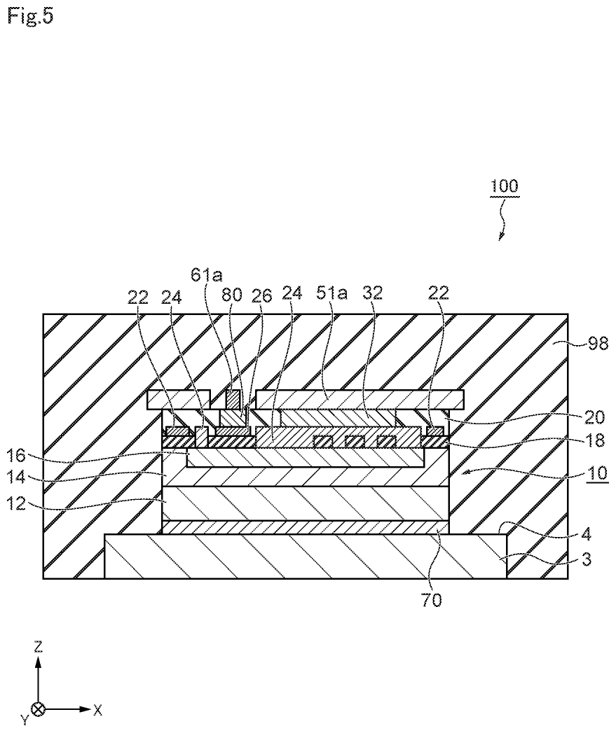

FIG. 1 is the schematic top view of the semiconductor device 100 according to the present embodiment. FIG. 2 is the schematic view of a cross section taken along line A-A′ in FIG. 1. FIG. 3 is the schematic view of a cross section taken along line B-B′ in FIG. 1. FIG. 4 is the schematic view of a cross section taken along line C-C′ in FIG. 1. FIG. 5 is a schematic cross-sectional view of the semiconductor device 100 according to the present embodiment. In FIG. 5, a sealing resin 98 is shown together. In the following drawings, the sealing resin 98 may be omitted.

The semiconductor device 100 of the present embodiment will be described with reference to FIGS. 1, 2, 3, and 4.

A die pad 2 is a member including a conductive material such as Cu on which the semiconductor chip 10 is disposed. The die pad 2 includes a first bed 3 and a first outer lead 6. The first bed 3 includes an upper surface 4. The semiconductor chip 10 is provided on the upper surface 4. The first outer lead 6 is connected to the first bed 3. The first outer lead 6 is used to connect the semiconductor chip 10 and an external circuit (not shown).

Here, an X direction, a Y direction perpendicular to the X direction, and a Z direction perpendicular to the X direction and the Y direction are defined. The upper surface 4 is arranged parallel to XY plane.

The semiconductor chip 10 is provided on the upper surface 4 of the die pad 2. In the semiconductor chip 10, for example, a vertical diode, a MOSFET, or an IGBT (Insulated Gate Bipolar Transistor) is provided on the semiconductor substrate such as a Si (silicon) substrate, a SiC (silicon carbide) substrate, or a GaAs (gallium arsenide) substrate, etc. or a semiconductor layer of GaN (gallium nitride), etc. on the Si substrate.

The semiconductor chip 10 has a rectangular shape when viewed from above. The semiconductor chip 10 includes a first side 10c, a second side 10d, a third side 10e, and a fourth side 10f. The first side 10c and the third side 10e face each other. The second side 10d and the fourth side 10f face each other.

For example, when the semiconductor chip 10 has a vertical n-channel MOSFET, the semiconductor chip 10 has an n-type semiconductor substrate 12, an n-type drift layer 14 provided on the semiconductor substrate 12, and a p-type well region 16 selectively provided on the drift layer 14. Here, the n-type impurity concentration of the drift layer 14 is higher than the n-type impurity concentration of the semiconductor substrate 12.

When viewed from above, the region in which the well region 16 is provided corresponds to the element region 10a of the MOSFET. Further, when viewed from above, the part of the drift layer 14 provided so as to surround the well region 16 corresponds to the termination region 10b (junction termination region) of the MOSFET. The element region 10a is a region in which a current flows when a predetermined forward voltage is applied to the semiconductor chip 10. The termination region 10b is a region for widening the depletion layer in the outer peripheral portion of the semiconductor chip 10 in order to hold the applied reverse voltage.

The first insulating film 18 is provided on the semiconductor chip 10. The first insulating film 18 includes, for example, an insulating material such as silicon oxide.

The first electrode 24 is provided on the semiconductor chip 10. The first electrode 24 is provided in the opening of the first insulating film 18, for example. When the semiconductor chip 10 includes the MOSFET, the first electrode 24 is, for example, the source electrode of the MOSFET. When the semiconductor chip 10 includes the IGBT, the first electrode 24 is, for example, the emitter electrode of IGBT. The first electrode 24 includes, for example, Al.

The second electrode 26 is provided on the semiconductor chip 10. When viewed from above, the size of the second electrode 26 is smaller than the size of the first electrode 24. The second electrode 26 is, for example, the gate electrode of the MOSFET or the IGBT. The second electrode 26 includes, for example, Al.

An electrode (not shown) is provided below the semiconductor chip 10. When the semiconductor chip 10 includes the MOSFET, such an electrode (not shown) is, for example, the drain electrode of the MOSFET. When the semiconductor chip 10 includes the IGBT, such an electrode (not shown) is, for example, the collector electrode of the IGBT.

A field plate electrode 22 is provided on the first insulating film 18 in the termination region 10b. The field plate electrode 22 is provided, for example, to reduce the electric field concentration at the time of applying a reverse-voltage between the source electrode and the drain electrode of MOSFET, thereby increasing the breakdown voltage. The field plate electrode 22 includes, for example, Al. The field plate electrode 22 can be connected to either the first electrode 24 or the second electrode 26 to reduce the electric field concentration. Therefore, the field plate electrode 22 is electrically connected to the first electrode 24 or the second electrode 26.

The second insulating film 20 is provided on the first insulating film 18, the first electrode 24, and the field plate electrode 22. The second insulating film 20 includes, for example. an insulating material such as polyimide.

The first bonding material 32 is provided on the first electrode 24. The first bonding material 32 is provided in the opening of the second insulating film 20, for example. The first bonding material 32 electrically connects the first electrode 24 and the first connector 50. In order to increase the bonding strength between the first electrode 24 and the first bonding material 32, a metallic film (not shown) may be provided between the first electrode 24 and the first bonding material 32. Such metallic film includes, for example, Ni (nickel) and Au (gold).

The second bonding material 80 is provided on the second electrode 26. The second bonding material 80 is provided in the opening of the second insulating film 20, for example. The second bonding material 80 electrically connects the second electrode 26 and the second connector 60. In order to increase the bonding strength between the second electrode 26 and the second bonding material 80, a metallic film (not shown) may be provided between the second electrode 26 and the second bonding material 80. Such metallic film includes, for example, Ni (nickel) and Au (gold).

The third bonding material 70 is provided between the semiconductor chip 10 and the upper surface 4. The third bonding material 70 electrically connects an unillustrated electrode (e.g., the drain electrode) of the semiconductor chip 10 and the upper surface 4.

The first post 54 includes a second bed 58 and a second outer lead 56. The first post 54 includes an electrically conductive material such as Cu. The second outer lead 56 is used for connecting the semiconductor chip 10 and an external circuit (not shown).

The second post 64 includes a third bed 68 and a third outer lead 66. The second post 64 includes an electrically conductive material such as Cu. The third outer lead 66 is used for connecting the semiconductor chip 10 and an external circuit (not shown).

A first connector 50 includes a first end 51a and a second end 51b. The first connector 50 includes, for example, an electrically conductive material such as Cu. Incidentally, the surface of the first connector 50 may be plated by a material containing, for example, Tin (Sn).

The first end 51a of the first connector 50 has a portion that, when viewed from above, covers each of the first side 10c, the second side 10d, the third side 10e, and the fourth side 10f of the rectangular shape of the semiconductor chip 10. In the case of the first end 51a shown in FIG. 1, the first end 51a completely covers the three sides of the rectangular shape when viewed from above. In other words, in the case of the first end 51a shown in FIG. 1, when viewed from above, the first end 51a completely covers the second side 10d, the third side 10e and the fourth side 10f. The first end 51a completely covers at least three sides of the rectangular shape when viewed from above. Note that the first end 51a shown in FIG. 1 has a slit 51s to provide the second connector 60, so that the first side 10c is not completely covered when viewed from above.

The first connector 50 shown in FIG. 1 is provided above (on) the termination region 10b and above (on) the element region 10a.

In addition, in a plane parallel to XY plane (the upper surface 4), an outer diameter L2 of the first end 51a of the first connector 50 in the X direction is larger than a length L1 of the semiconductor chip 10 in the X direction. In a plane parallel to XY plane, a length L4 of the first end 51a of the first connector 50 in the Y direction is longer than a length L3 of the semiconductor chip 10 in the Y direction. In this way, in a plane parallel to XY plane (the upper surface 4), the first connector 50 has a portion in the X direction and the Y direction that is longer than the length of the semiconductor chip 10. In other words, the first connector 50 has a protrusion in an eaves shape outward from each side (the first side 10c, the second side 10d, third side 10e, and fourth side 10f) of the semiconductor chip 10.

Note that the first connector 50 and the second insulating film 20 may be in contact with each other as illustrated in FIGS. 2, 3, and 4. Further, the first connector 50 and the second insulating film 20 may be provided separately from each other. However, from the viewpoint of improving the heat dissipation property of the semiconductor chip 10, the first connector 50 and the second insulating film 20 are preferably in contact with each other.

The second end 51b is provided on the second bed 58.

A fourth bonding material 59 is provided between the second bed 58 and the second end 51b. The fourth bonding material 59 joins the second bed 58 and the second end 51b. Accordingly, the first connector 50 is electrically connected to the first post 54.

The second connector 60 has a third end 61a and a fourth end 61b. The second connector 60 includes, for example, an electrically conductive material such as Cu. Incidentally, the surface of the second connector 60 may be plated by a material containing, for example, Sn. The third end 61a is provided in the slit 51s provided in the first end 51a. When viewed from above, the second bonding material 80 is provided in the slot 51s. The third end 61a is electrically connected to the second electrode 26 of the semiconductor chip 10 via the second bonding material 80.

As shown in FIG. 4, the second connector 60 is preferably not as far away from the semiconductor chip 10 as possible on the semiconductor chip 10. The second connector 60 has a first part 62a connected to the second electrode 26 via the second bonding material 80 and a second part 62b connected to the first part 62a. The first part 62a has the third end 61a. It is preferable that a distance d1 between the first part 62a and the upper surface 4 be longer than a distance d2 between the second part 62b and the upper surface 4. In addition, it is preferable that the termination region 10b of the semiconductor chip 10 is not provided below the second part 62b.

Incidentally, the first connector 50 and the second connector 60 can not be easily bent and are hard connectors, which are different from wires used for bonding.

A fifth bonding material 69 is provided between the third bed 68 and the fourth end 61b. The fifth bonding material 69 joins the third bed 68 and the fourth end 61b. Accordingly, the second connector 60 is electrically connected to the second post 64.

The first connector 50 and the first post 54 may be integrally formed. Further, the second connector and the second post 64 may be integrally formed.

As the first bonding material 32, the second bonding material 80, the third bonding material 70, the fourth bonding material 59, and the fifth bonding material 69, for example, a solder containing Pb (lead) and Sn (tin), a solder containing Pb, Ag (silver) and Sn (tin), a solder containing Sn and Sb (antimony), a solder containing Au (gold) and Sn, a solder containing Au and Si, a solder containing Au and Ge (germanium), a silver paste, or the like can be preferably used.

FIG. 5 is a schematic cross-sectional view of the semiconductor device of the present embodiment. As shown in FIG. 5, the semiconductor device 100 is sealed by the sealing resin 98 and is used. For example, the sealing resin is provided to seal the periphery of the semiconductor chip 10 and the first connector 50. Here, the sealing resin 98 is, for example, an epoxy-resin. The sealing resin 98 may further contain a filler such as silica.

Next, the operation and effects of semiconductor device of the present embodiment will be described.

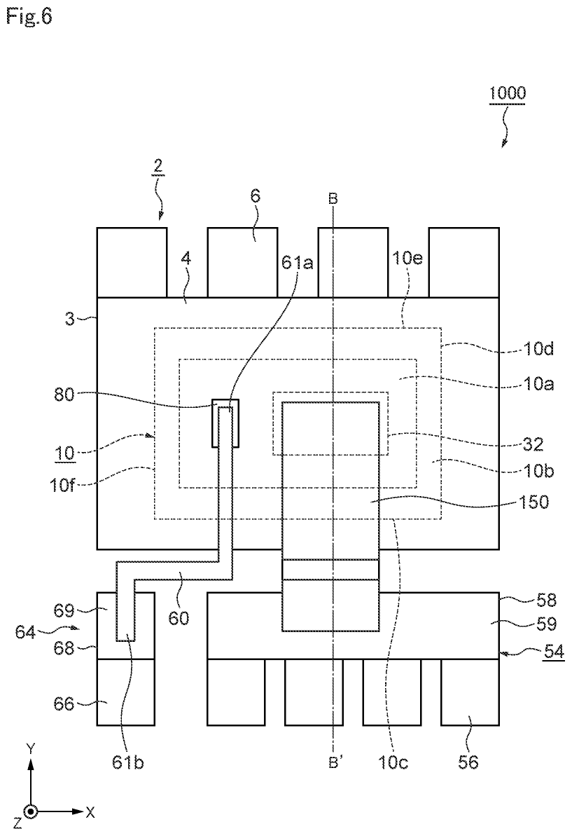

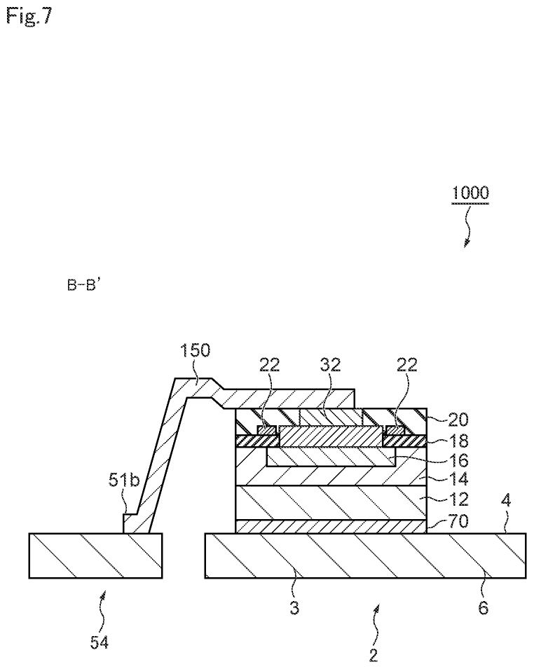

FIG. 6 is a schematic the upper surface diagram of the semiconductor device 1000 as a comparative embodiment of the present embodiment. FIG. 7 is a schematic cross-sectional view of the semiconductor device 1000 according to a comparative embodiment of the present embodiment. When viewed from above, the first connector 150 does not cover the second side 10d, the third side 10e, and the fourth side 10f.

In order to maintain the reverse blocking voltage, the vertical power the semiconductor device as in the present embodiment can maintain a higher reverse blocking voltage by spreading the depletion layer in the vertical direction (Z direction) inside the semiconductor chip 10 in accordance with the voltage. At this time, the outer peripheral portion of the semiconductor chip 10 is designed so that the chip-side surface has the same electric potential as the reverse blocking voltage. Here, the reverse blocking voltage is a breakdown voltage.

In addition, the semiconductor chip 10 has the termination region 10b designed so as not to reach the end of the semiconductor chip 10 while spreading the depletion layer in the lateral direction (a direction parallel to XY plane). Thus, a high reverse blocking voltage is maintained.

The termination region 10b is designed to have a high breakdown voltage with respect to the element region 10a, and generally has a high avalanche capability at the time of an L load (inductive load). In the termination region 10b, in order to obtain a high breakdown voltage with respect to the element region 10a, it is essential to design the voltage value of the termination region 10b becomes equal to or higher than the voltage value of the element region 10a in the case that a voltage higher than the element region 10a is applied to the termination region 10b, the depletion layer spreads over the entire termination region, the electric field peak exceeds the critical electric field defined by the semiconducting material such as Si, and yields avalanche.

Here, if the electric field peak of the termination region 10b is locally too high, the electric field distribution in the semiconductor chip 10 may be changed due to the occurrence of hot carrier injection, and the breakdown voltage may be lowered. Further, if a movable ion such as a sodium ion contained in the sealing resin 98, water, or the like is present on the termination region 10b, the electric field profile of the termination region may be changed due to the electric charges possessed by such ions, and the breakdown voltage may be lowered.

Therefore, the semiconductor device 100 of the present embodiment includes the first connector 50 provided above (on) the termination region 10b and having a portion that covers each of four sides of a rectangular shape when viewed from above, and is electrically connected to the first electrode 24.

The movable ions are attracted to the first connector 50 by electrostatic attraction. For example, if the semiconductor chip 10 has an n-type MOSFET, movable ions, such as positively charged sodium ions, are attracted to the first connector 50, which is at a low electric potential (Lo potential). Since the first connector 50 has a portion covering each of the four sides of the rectangular shape when viewed from above, the movable ions are difficult to penetrate onto the termination region 10b of the semiconductor chip 10. This makes it possible to provide the semiconductor device with high reliability. In particular, it is preferable that the first connector 50 completely covers the three sides of the rectangular shape when viewed from above.

It is preferable that the distance d1 between the first part 62a and the upper surface 4 is longer than the distance d2 between the second part 62b and the upper surface 4. In addition, it is preferable that the termination region 10b of the semiconductor chip 10 is not provided below the second part 62b. The electric potential of the second connector 60 is kept relatively low because the second connector 60 is connected to the second electrode 26. Then, the movable ions can be attracted to the second connector 60 and it becomes difficult for the movable ions to penetrate onto the semiconductor chip 10.

According to the semiconductor device of the present embodiment, a highly reliable semiconductor device can be provided.

### Second Embodiment

The semiconductor device of the present embodiment differs from the semiconductor device of the first embodiment in that the first connector has an eaves portion extending outwardly from the semiconductor chip, and a distance between the eaves portion and the upper surface is shorter than a distance between the first connector above the semiconductor chip and the upper surface. Here, description of the same content as that of the first embodiment is omitted.

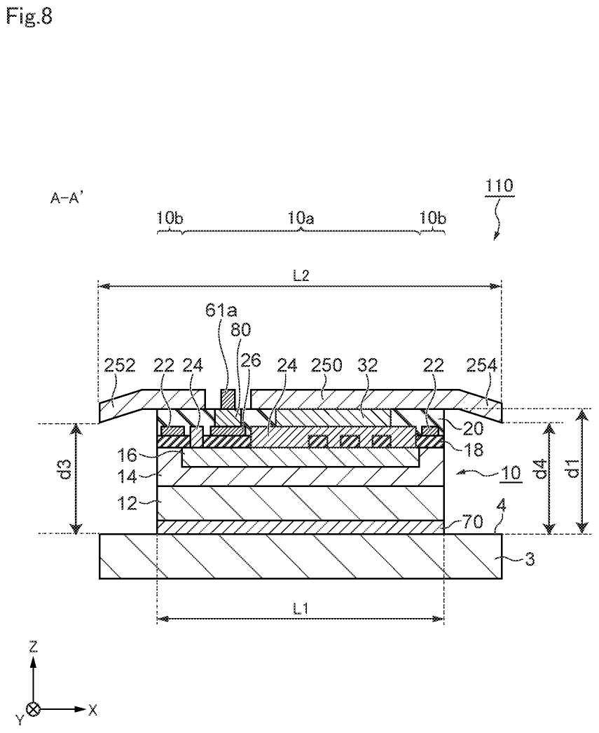

FIG. 8 is a schematic cross-sectional view of the semiconductor device 110 according to the present embodiment. The first connector 250 has a first eaves portion 252 (an exemplary eaves portion) extending outwardly from the semiconductor chip 10 and a second eaves portion 254 extending outwardly from the semiconductor chip 10. The length L2 of the first connector 250 in the X direction is longer than the length L1 of the semiconductor chip in the X direction. In the Z direction, the distance d3 between the first eaves portion 252 and the upper surface 4 of the die pad 2 is shorter than the distance d1 between the first connector 50 above the semiconductor chip 10 and the upper surface 4 of the die pad 2. Further, in the Z direction, the distance d4 between the second eaves portion 254 and the upper surface 4 of the die pad 2 is shorter than the distance d1 between the first connector 50 above the semiconductor chip 10 and the upper surface 4 of the die pad 2.

According to the semiconductor device 110 of the present embodiment, since the first eaves portion 252 and the second eaves portion 254 are bent toward the upper surface 4, it is possible to further suppress the invasion of movable ions between the semiconductor chip 10 and the first connector 50.

According to the semiconductor device of the present embodiment, a highly reliable semiconductor device can be provided.

### Third Embodiment

The semiconductor device of the present embodiment differs from the semiconductor device of the first and second embodiments in that the first connector has an eaves portion extending outwardly from the semiconductor chip, and a distance between the eaves portion and the upper surface is longer than a distance between the first connector above the semiconductor chip and the upper surface. Here, description of contents overlapping with the first and second embodiments is omitted.

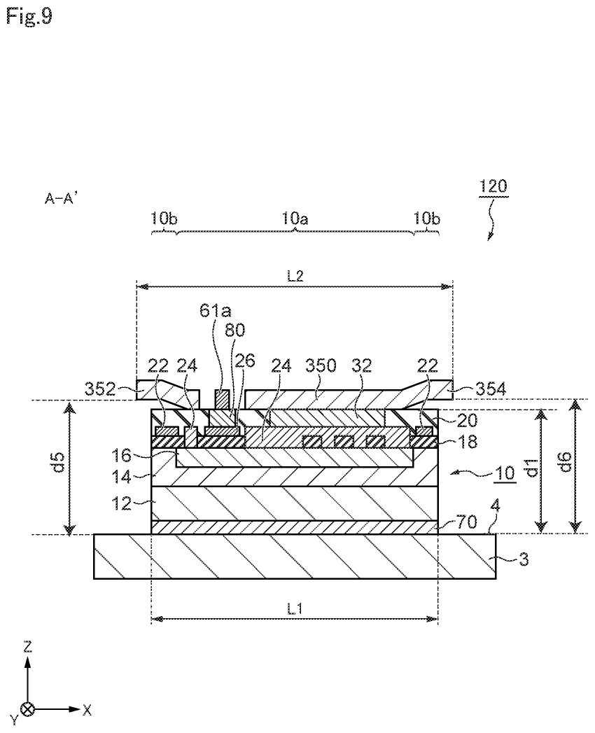

FIG. 9 is a schematic cross-sectional view of a semiconductor device 120 according to the present embodiment. The first connector has a third eaves portion 352 (an exemplary eaves portion) extending outwardly from the semiconductor chip 10 and a fourth eaves portion 354 extending outwardly from the semiconductor chip 10. In the Z direction, the distance d5 between the third eaves portion 352 of the first connector 350 and the upper surface 4 of the die pad 2 is longer than the distance d1 between the first connector 350 above the semiconductor chip 10 and the upper surface 4 of the die pad 2. Further, in the Z direction, the distance d6 between the fourth eaves portion 354 of the first connector 350 and the upper surface 4 of the die pad 2 is longer than the distance d1 between the first connector 350 above the semiconductor chip 10 and the upper surface 4 of the die pad 2.

At the end of the first connector, the electric potential changes rapidly. Therefore, breakage is likely to occur when a high voltage is applied. Therefore, in the semiconductor device 120 of the present embodiment, the distance between the end of the first connector 350 and the upper surface 4 of the die pad 2 is set to be longer than the distance between the first connector above the semiconductor chip 10 and the upper surface 4 of the die pad 2. Therefore, a sudden change in the electric potential of the first connector at the end can be generated in a wider space, particularly in the Z direction. As a result, such breakdown can be suppressed, and thus a higher breakdown voltage can be ensured.

According to the semiconductor device of the present embodiment, a highly reliable semiconductor device can be provided.

### Fourth Embodiment

The semiconductor device of the present embodiment is different from the semiconductor device of the first to third embodiments in that the semiconductor device further includes a first post provided separately from the die pad; and a second post provided separately from the die pad and the first post; wherein the first connector is electrically connected to the first post, the first connector has a first through hole provided above (on) the second electrode, and the second post is electrically connected to the second electrode by a conductor passing through the first through hole. Here, descriptions of the same contents as those of the first to third embodiments are omitted.

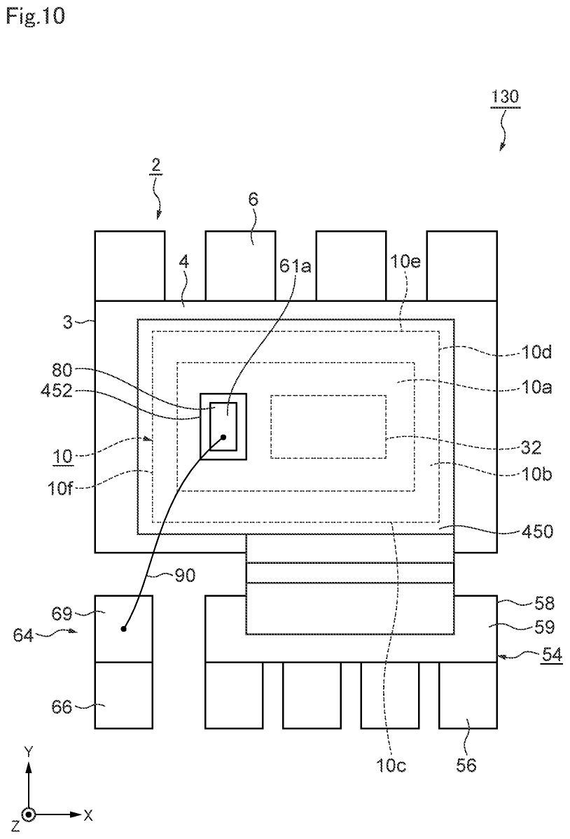

FIG. 10 is a schematic top view of the semiconductor device 130 according to the present embodiment.

The first connector 450 has a first through hole 452 provided above (on) the second electrode 26. The second post 64 is electrically connected to the second electrode 26 and the second bonding material 80 via the first through hole 452. In FIG. 10, the second electrode 26 and the second post 64 are electrically connected by an electric conductor such as the wire 90 passing through the first through hole 452. However, the second electrode 26 and the second post 64 may be connected by an electric conductor such as a connector passing through the first through hole 452. Note that the second bonding material 80 and the fifth bonding material 69 may not be provided.

According to the semiconductor device 130 of the present embodiment, when viewed from above, it is possible to completely cover the first side 10c, the second side 10d, the third side 10e, and the fourth side 10f of the semiconductor chip 10. This makes it difficult for the mobile ions to penetrate further onto the semiconductor chip 10.

According to the semiconductor device of the present embodiment, a highly reliable semiconductor device can be provided.

### Fifth Embodiment

The semiconductor device of the present embodiment is different from the semiconductor device of the first to fourth embodiments in that the first connector includes a plurality of through holes. Here, descriptions of the same contents as those of the first to fourth embodiments are omitted.

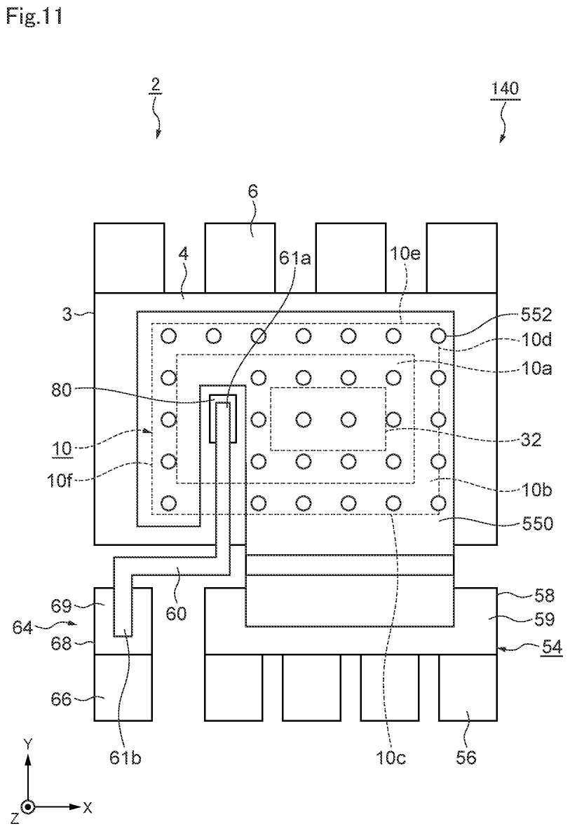

FIG. 11 is a schematic top view of the semiconductor device 140 according to the present embodiment. A plurality of through holes 552 are provided at the first end of the first connector 550. The first bonding material 32, for example, is provided inside the through hole 552. The sealing resin 98, for example, is provided inside the through hole 552. The through hole 552 may be, for example, a recess or a slit. In addition, the through hole 552 may be provided only in a part where the first bonding material 32 is provided on the first electrode 24.

For example, if the quantity of the first bonding material 32 is too much, the first bonding material 32 may enter the through hole 552. In this way, for example, the problem that the first bonding material 32 remains on the second insulating film 20, and the reliability of the second insulating film 20 is degraded, can be solved.

Further, for example, when the sealing resin 98 enters the inside of the through hole 552, the adhesion between the first connector and the sealing resin 98 can be improved. As a result, the reliability of the semiconductor device can be further increased.

According to the semiconductor device of the present embodiment, a highly reliable semiconductor device can be provided.

### Sixth Embodiment

The semiconductor device of the present embodiment is different from the semiconductor device of the first to fifth embodiments in that the second electrode 26 is provided at a corner of the element region 10a. Here, descriptions of the same contents as those of the first to fifth embodiments are omitted.

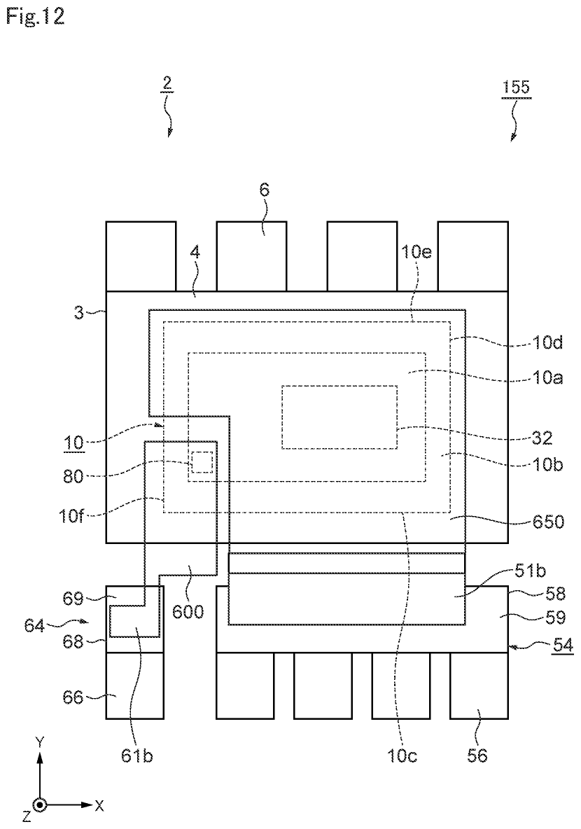

FIG. 12 is a schematic top view of the semiconductor device 155 according to the present embodiment. The second electrode 26 and the second bonding material 80 are provided at a corner of the element region 10a. Alternatively, the second electrode 26 and the second bonding material 80 are provided around the corner of the semiconductor chip 10. The first connector 650 does not cover the second electrode 26 and the second bonding material 80 when viewed from above. The second connector 600 electrically connects the second electrode 26 and the second bonding material 80 to the second post 64.

According to the semiconductor device of the present embodiment, a highly reliable semiconductor device can be provided.

### Seventh Embodiment

The semiconductor device of the present embodiment includes a first post provided separately from the die pad; and a second post provided separately from the die pad and the first post; wherein the first connector completely covers the four sides of the rectangular shape when viewed from above, the first connector includes a second through hole provided above (on) the element region, the first connector is electrically connected to the first post, the first electrode is electrically connected to the first post by a second wire passing through the second through hole, and the second electrode is electrically connected to the second post via the second through hole by a third wire passing through the second through hole. Here, descriptions of the same contents as those of the first to sixth embodiments are omitted.

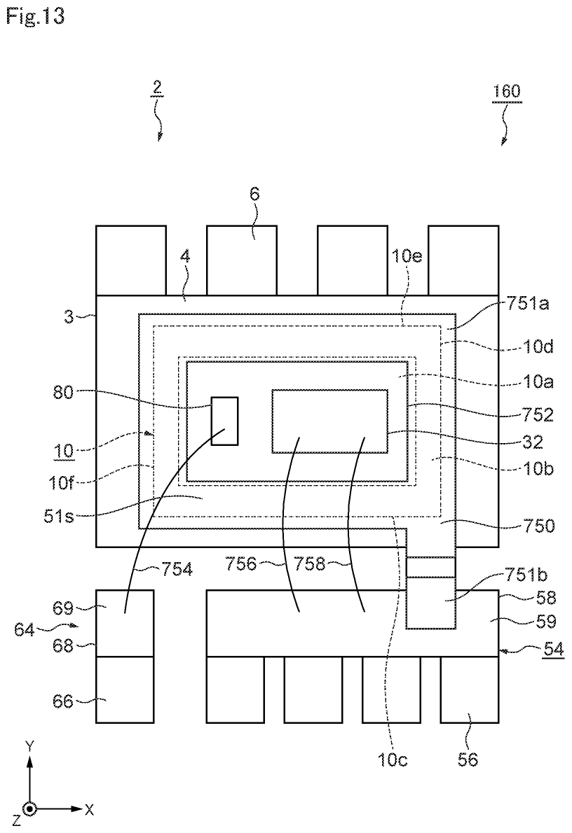

FIG. 13 is a schematic top view of the semiconductor device 160 according to the present embodiment.

The first connector 750, when viewed from above, completely covers the termination region 10b, the first side 10c, the second side 10d, the third side 10e and the fourth side 10f. The first connector 750 is fixed by, for example, a bonding material (not shown). The first connector 750 may be fixed, for example, by being in contact with the second insulating film 20.

The first connector 750 has a second through hole 752 provided above (on) the element region 10a. The first electrode 24 and the second electrode 26 are provided in the second through hole 752 when viewed from above.

The first electrode 24 and the first bonding material 32 are electrically connected to the first post 54 by electric conductors such as the second wire 756 and the second wire 758 passing through the second through hole 752. The second end 751b of the first connector 750 is electrically connected to the first post 54. Thus, the first electrode 24 and the first bonding material 32 are electrically connected to the first end 751a of the first connector 750 via the second the wire 756, the second the wire 758, the first post 54, and the second end 751b. Note that an electric conductor such as a connector may be used instead of the second the wire 756 and the second the wire 758.

The second electrode 26 and the second bonding material 80 are electrically connected to the second post 64 by a conductor such as a third the wire 754 passing through the second through hole 752. Note that a conductor such as a connector may be used instead of the third the wire 754.

According to the semiconductor device of the present embodiment, four sides (the first side 10c, the second side 10d, third side 10e, and fourth side 10f) of the termination region 10b and the rectangular shape of the semiconductor chip 10 can be completely covered.

According to the semiconductor device of the present embodiment, a highly reliable semiconductor device can be provided.

### Eighth Embodiment

The semiconductor device of the present embodiment includes a first post provided separately from the die pad; and a second post provided separately from the die pad and the first post; wherein the first connector completely covers the four sides of the rectangular shape when viewed from above, the first connector includes a second through hole provided above (on) the element region, the first connector is electrically connected to the first electrode via a bonding material above (on) the element region, the first electrode is electrically connected to the first post by a second wire passing through the second through hole, and the second electrode is electrically connected to the second post by a third wire passing through the second through hole. Here, descriptions of the same contents as those of the first to seventh embodiments are omitted.

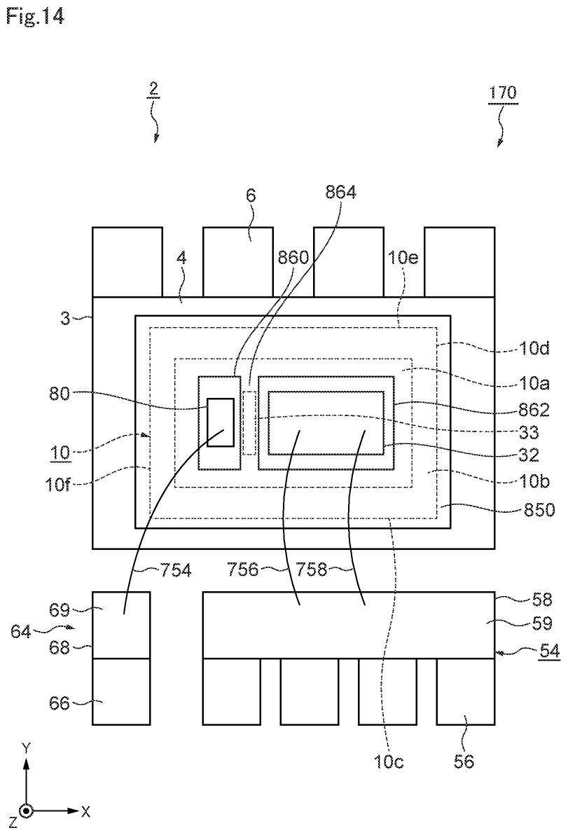

FIG. 14 is a schematic top view of the semiconductor device 170 of the present embodiment. Unlike the first connector 750 of the seventh embodiment, the first connector 850 of the present embodiment is an electric conductor that does not have the second end.

The first connector 850 has a bridging extension portion 864. A bonding material 33 is provided below the extension portion 864. The bonding material 33 is provided in, for example, the opening (not shown) provided in the second insulating film 20, and is electrically connected to the first electrode 24. The first connector 850 is electrically connected to the first electrode 24 via the extension portion 864 and the bonding material 33. In this manner, the first connector 850 is electrically connected to the first electrode 24 above (on) the element region 10a. The first electrode 24 is provided, for example, below the first bonding material 32 and the bonding material 33. The manner in which the first connector 850 and the first electrode 24 are electrically connected above (on) the element region 10a is not limited to the above-described embodiment. For example, the first connector 850 may be fixed by a bonding material (not shown). Further, for example, the first connector 850 may be fixed by being in contact with the second insulating film 20.

A through hole 860 of the first connector 850 is provided above (on) the second bonding material 80. A through hole 862 of the first connector 850 is provided above (on) the first bonding material 32. The through hole 860 and the through hole 862 are examples of the second through hole.

According to the semiconductor device of the present embodiment, a highly reliable semiconductor device can be provided.

The above explanation is based on a SMD (Surface Mount Device) type the semiconductor device. However, the semiconductor device of the present embodiment is not limited to the SMD type semiconductor device. For example, the semiconductor device of the present embodiment may be a THD (Through Hole Device) type semiconductor device.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a die pad including an upper surface;
a semiconductor chip provided on the upper surface, the semiconductor chip including a rectangular shape, and the semiconductor chip including
an element region, and
a termination region surrounding the element region;
a first electrode provided on the semiconductor chip;
a second electrode provided on the semiconductor chip;
a first connector provided above the termination region, the first connector including a portion covering each of the four sides of the rectangular shape when viewed from above, and the first connector being electrically connected to the first electrode; and
a sealing resin sealing a periphery of the semiconductor chip and the first connector.

2. The semiconductor device according to claim 1, wherein
the first connector completely covers at least three sides of the rectangular shape when viewed from above.

3. The semiconductor device according to claim 1, wherein
the first connector has an eaves portion extending outwardly from the semiconductor chip, and
a distance between the eaves portion and the upper surface is shorter than a distance between the first connector above the semiconductor chip and the upper surface.

4. The semiconductor device according to claim 1, wherein
the first connector has an eaves portion extending outwardly from the semiconductor chip, and
a distance between the eaves portion and the upper surface is longer than a distance between the first connector above the semiconductor chip and the upper surface.

5. The semiconductor device according to claim 1, further comprising:
a first post provided separately from the die pad; and
a second post provided separately from the die pad and the first post;
wherein
the first connector is electrically connected to the first post,
the first connector has a first through hole provided above the second electrode, and
the second post is electrically connected to the second electrode by a conductor passing through the first through hole.

6. The semiconductor device according to claim 1, further comprising:
a second post provided separately from the die pad; and
a second connector electrically connected to the second post, the second connector including
a first portion electrically connected to the second electrode, and
a second portion connected to the first portion, a distance between the second portion and the upper surface is longer than a distance between the first portion and the upper surface.

7. The semiconductor device according to claim 1, further comprising:
a first post provided separately from the die pad; and
a second post provided separately from the die pad and the first post;
wherein
the first connector completely covers the four sides of the rectangular shape when viewed from above,
the first connector includes a second through hole provided above the element region,
the first connector is electrically connected to the first post,
the first electrode is electrically connected to the first post by a second wire passing through the second through hole, and
the second electrode is electrically connected to the second post via the second through hole by a third wire passing through the second through hole.

8. The semiconductor device according to claim 1, further comprising:
a first post provided separately from the die pad; and
a second post provided separately from the die pad and the first post;
wherein
the first connector completely covers the four sides of the rectangular shape when viewed from above,
the first connector includes a second through hole provided above the element region,
the first connector is electrically connected to the first electrode via a bonding material above the element region,
the first electrode is electrically connected to the first post by a second wire passing through the second through hole, and
the second electrode is electrically connected to the second post by a third wire passing through the second through hole.

9. The semiconductor device according to claim 1, further comprising:
a second post provided separately from the die pad; and
a second connector provided in a slot of the first connector, and the second connector electrically connecting the second electrode and the second post.

10. The semiconductor device according to claim 1, wherein
when viewed from above, a size of the second electrode is smaller than a size of the first electrode.

11. The semiconductor device according to claim 1, further comprising:
an insulating film provided on the semiconductor chip, the insulating film being in contact with the first connector.

12. The semiconductor device according to claim 1, wherein
the first connector includes a plurality of through holes.

13. The semiconductor device according to claim 12, wherein
the sealing resin is provided inside the through holes.

14. The semiconductor device according to claim 12, further comprising:
a first bonding material joining the first electrode and the first connector,
wherein the first bonding material is provided inside the through holes.

15. The semiconductor device according to claim 1, wherein
second electrode is provided at a corner of the element region.
